(19) United States
(12) Patent Application Publication
(10) Pub. No.: US 2026/0246436 A1
(43) Pub. Date: Aug. 20, 2026

(54) NORMALIZATION CIRCUIT AND RELATED ELECTRONIC SYSTEM

(71) Applicant: STMicroelectronics International N.V., Geneva (CH)

(72) Inventors: Stefano PASSI, Pavia (IT); Mehran Gholami, Pavia (IT); Francesco D'angelo, Giussago (PV) (IT); Alessandro Cabrini, San Genesio Ed Uniti (IT); Giulio Ricotti, Broni (PV) (IT)

(21) Appl. No.: 19/542,154

(22) Filed: Feb. 17, 2026

(30) Foreign Application Priority Data
Feb. 18, 2025 (IT) 102025000003126

(51) Int. Cl. H03G 3/30; G01R 19/04; H02M 3/156; H03M 1/06

(52) U.S. Cl. CPC H03G 3/30; G01R 19/04; H03M 1/0607; H02M 3/156

(57) ABSTRACT

A normalization circuit has a first circuit path, implementing a high pass filtering of an input signal to provide a high-pass filtered component being a function of an AC component of the input signal, a second circuit path, implementing a low pass filtering of the input signal to provide a low-pass filtered component being a function of a DC-shift component of the input signal, and a summing stage, which is coupled at the outputs of the first and second circuit paths to provide at a respective output, a sum signal as a function of the sum of the high-pass and low-pass filtered components. The normalization circuit has a gain stage to set a common gain factor for the AC and DC-shift components of the input signal, so that the respective output of the summing stage provides an output signal as a result of a normalization of the input signal.

### CROSS-REFERENCE TO RELATED APPLICATIONS

This application claims the benefit of Italian Patent Application No. 102025000003126, filed on Feb. 18, 2025, which application is hereby incorporated herein by reference.

### TECHNICAL FIELD

The present solution relates to an improved normalization circuit, in particular for real-time normalization operations, and to a related electronic system.

### BACKGROUND

As is known, real-time data normalization is often required in electronic systems, for example to ensure that different features may contribute equally to a comparison analysis. Without normalization, features with larger ranges could disproportionately influence the comparison.

Normalization operations are for example required in power electronic systems, for example for real-time component health monitoring, power converter diagnostics, capacitor degradation detection, system reliability assessment, predictive maintenance.

Normalization operations are also often required in data acquisition systems, industrial automation, process control systems and, in the field of machine learning hardware, for neural network pre-processing, real-time data preparation, hardware-accelerated AI (Artificial Intelligence) systems.

Data normalization operations are often required before feeding input data to processing units, which are configured to implement suitable processing algorithms or neural networks.

Commonly used normalization solutions are based on a digital conversion of the signals to be normalized, using analog to digital converters (ADC), followed by suitable digital operations (e.g. digital divisions).

Such digital solutions may however have some drawbacks.

For example, quantization errors may not be acceptable for applications requiring precise data processing, since quantization noise may change the (normalized) input data integrity and cause processing errors.

If it is required to normalize and differentiate very small changes in the signals (for example, even as small as 100 microvolts in voltage signals), the number of bits needed is increased and implementation of these solutions may be very challenging, if not impossible, when limited space is available for implementing the processing unit.

Moreover, problems are commonly associated with digital divisions, such as precision and rounding errors, overflow and underflow, divide-by-zero errors and limited dynamic range.

### SUMMARY

The present solution generally aims to overcome the limitations of known normalization systems and to provide an answer to the aforementioned need for real-time signal normalization.

According to the present solution, a normalization circuit and a corresponding electronic system are provided, as defined in the attached claims.

According to the present solution, a comparison circuit and a corresponding electronic system are provided, as defined in the attached claims.

### BRIEF DESCRIPTION OF THE DRAWINGS

For a better understanding of the present invention, a preferred embodiment thereof is now described, purely by way of non-limiting example and with reference to the attached drawings, wherein:

FIG. 1 shows a graphic depiction of a normalization operation of an input signal;

FIG. 2 shows the plot of an exemplary input signal to be normalized;

FIG. 3 is a block diagram of a normalization circuit according to an embodiment of the present solution;

FIG. 4 is a fully analog circuit implementation of the normalization circuit according to an embodiment of the present solution;

FIG. 5 is a schematic block diagram of an electronic system including the normalization circuit;

FIG. 6 is a schematic block diagram of a known (by itself) device;

FIG. 7 is a schematic block diagram of a comparison circuit according to an embodiment of the present solution; and

FIG. 8 is a fully analog circuit implementation of the comparison circuit of FIG. 7.

### DETAILED DESCRIPTION OF ILLUSTRATIVE EMBODIMENTS

As will be described in detail below, one aspect of the present solution relates to a circuit implementation of a mathematical approach to normalization, in particular to min-max normalization, denoted as “mapminmax” in MATLAB®.

In particular, according to an embodiment of the present solution, the normalization does not require an operation of digital conversion of the input signals and is implemented through a pure analog circuitry.

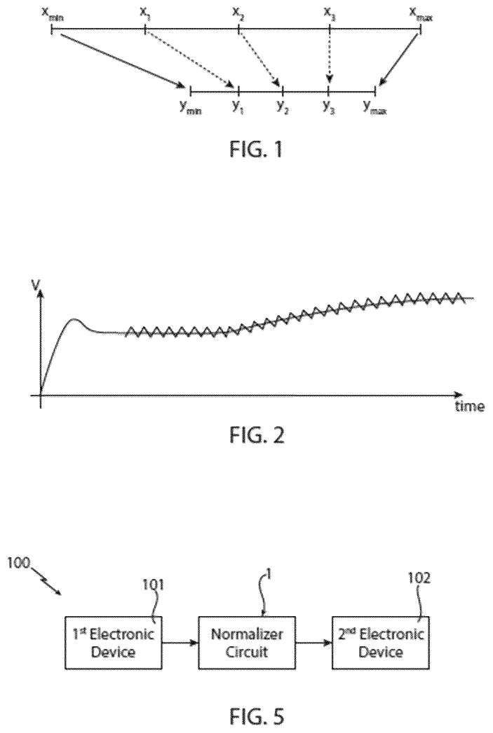

The implemented min-max normalization, as schematically shown in FIG. 1, is designed to map an input x, with values within a range comprised between xₘᵢₙ (minimum input value) and xₘₐₓ (maximum input value), into an output y, with values within a range comprised between yₘᵢₙ (minimum output value) and yₘₐₓ (maximum output value); commonly yₘᵢₙ and yₘₐₓ are set to a negative, respectively positive, value, having an equal absolute value (for example to −1 and, respectively, +1).

In detail, the min-max normalization formula has the following mathematical expression:

$$y = ( \frac{( {y}_{max} - {y}_{min} ) \cdot ( x - {x}_{min} )}{{x}_{max} - {x}_{min}} ) + {y}_{min}$$

The values x_min and xₘₐₓ are generally known or can be determined, e.g. via a peak detector circuit applied to the input signal. These xₘᵢₙ and xₘₐₓ values can also be extracted from a data set used to train a neural network, from the statistic range of all possible values, assumed by input x.

Analyzing in more detail the above min-max normalization formula:
the term (x−xₘᵢₙ) shifts the input x to start from zero;
the term (xₘₐₓ−xₘᵢₙ) defines the width of the input range;
the term

$$\frac{( x - {x}_{min} )}{( {x}_{max} - {x}_{min} )}$$

realizes the input x to a value between 0 and 1;
the term (yₘₐₓ−yₘᵢₙ) defines the width of the output range;
the term

$$( {y}_{max} - {y}_{min} ) \cdot \frac{( x - {x}_{min} )}{( {x}_{max} - {x}_{min} )}$$

scales the normalized input x to the width of the output range;
the term +yₘᵢₙ shifts the result to start at yₘᵢₙ.

The Applicant has realized that the above formula may be modified, or reformulated, in view of its circuit implementation.

In particular, it is first assumed, by way of example, that yₘₐₓ=K and yₘᵢₙ=−K (where K can be, for example, equal to 1, as discussed above), so that: (yₘₐₓ−yₘᵢₙ)=2K. The above formula may then be rewritten as:

$$y = 2 K \cdot \frac{( x - {x}_{min} )}{{x}_{max} - {x}_{min}} - K = \frac{2 K x - 2 K {x}_{min} - K {x}_{max} + K {x}_{min}}{{x}_{max} - {x}_{min}} =$$

$$\frac{2 K x - K {x}_{min} - K {x}_{max}}{{x}_{max} - {x}_{min}} = \frac{2 K [ x - {x}_{min} / 2 - {x}_{max} / 2 ]}{{x}_{max} - {x}_{min}}$$

The term 2K/(xₘₐₓ−xₘᵢₙ) is a constant value, so that it can be considered as a constant amplification or gain factor G.

The formula can thus be further modified as follows:

$$y = G \cdot [ x - \frac{{x}_{min}}{2} - \frac{{x}_{max}}{2} ] = G \cdot [ x - \frac{( {x}_{min} + {x}_{max} )}{2} ]$$

The term

$$\frac{( {x}_{min} + {x}_{max} )}{2}$$

can be considered, for example in a continuous real time processing, as the average or constant (i.e., DC) value or component of the input signal x, so that the formula can be further modified as follows:

$$y = G \cdot [ x - {x}_{D C} ]$$

wherein the term x_{DC} represents the above referenced DC component of the input signal x.

In particular, the Applicant has further considered that the DC component of the input signal x may generally be subject to slow variations or shifts over time (these slow varying DC shifts may be particularly significant when the signals to be normalized are used to perform analyses over longer times, when gradual, long-term DC changes may have an impact on the analysis results).

According to the above, the input signal can be expressed as:

$$x = {x}_{DC} + {x}_{{DC}^{′}} + {x}_{A C}$$

where x_{DC′} represents the DC shift component, superimposed on the DC component x_{DC} and x_{AC} the rapidly variable, AC, component of the same input signal x.

This is exemplified in the plot of FIG. 2, which shows, as an example of the input signal x to be normalized, a voltage signal V at the output of a voltage converter, e.g. a Buck voltage converter. This voltage signal V has an AC ripple, at a switching frequency fₛ, superimposed on a DC component, having a slow variation over time.

The above formula therefore can be rewritten as follows:

$$y = G \cdot [ x - {x}_{D C} ] = G \cdot [ {x}_{D C} + {x}_{{DC}^{′}} + {x}_{A C} - {x}_{D C} ] = G \cdot {x}_{{DC}^{′}} + G \cdot {x}_{A C}$$

In other words, the result of the min-max normalization, i.e. the output signal y, can be expressed as the sum of a (slow varying) DC shift component and of a (rapidly variable) AC component of the same input signal x, both multiplied by a same gain factor G.

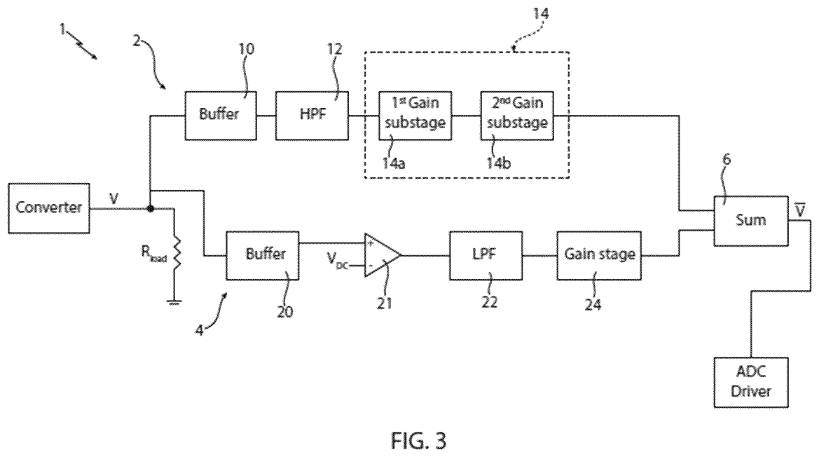

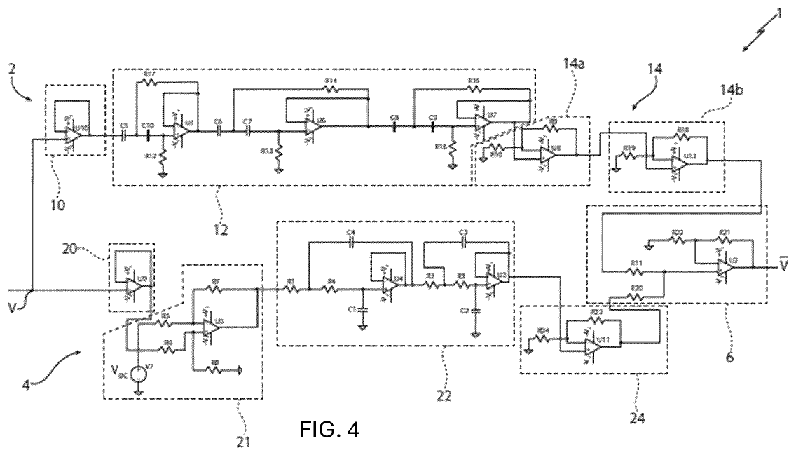

Starting from these considerations, an embodiment of a normalization circuit, implementing the above analyzed formula, is now discussed with reference to FIG. 3.

The normalization circuit, denoted as a whole with 1, receives in the example a voltage V, which represents the input signal x (this voltage V may for example be similar to the signal shown in FIG. 2 and can be received from a power converter device).

However, it is underlined that the normalization circuit 1 can operate on any voltage signal (with any signal shape) received at the input from any analog circuits, directly supplied to it or obtained by processing of other signals (for example, generated starting from a current signal).

The normalization circuit 1 comprises: a first circuit path 2, configured to implement a high pass filtering of the input signal and to provide at the output a high-pass filtered component being a function of the AC changes of the signal; and a second circuit path 4, configured to implement a low pass filtering of the same input signal and to provide at the output a low-pass filtered component being a function of the DC shifts of the signal; and a summing (or adder) stage 6, which is coupled at the outputs of the first and second circuit paths 2, 4 so as to provide at a respective output, a sum signal as a function of the sum of the high-pass and low-pass filtered components (and thus of the AC level and DC level changes of the signal).

The normalization circuit 1 is further configured to set an amplification in common for the AC and DC-shift components of the signal (the above gain factor G), so that the output of the summing stage 1 provides the output y of the normalization circuit 1 (which, as an example, oscillates in a symmetrical range centered around zero, between −K and K, e.g. between −1 and 1).

In the embodiment shown in FIG. 3, the first circuit path 2 is configured to perform a high-pass filtering and amplification (by the gain factor G) of the input signal (in this case, of the voltage V), so as to provide at a corresponding output a first amplified filtered signal G·V_{AC} (corresponding to the product term G·x_{AC} in the above formula); and the second circuit path 4 is configured to perform a low-pass filtering and amplification (by the same gain factor G) of the input signal (in this case, of the voltage V), so as to provide at a respective output a second amplified filtered signal G·V_{DC′} (corresponding to the product term G·x_{DC′} in the above formula).

The summing stage 6 receives the first and second amplified filtered signals and provides at the respective output a sum signal G·V_{AC}+G·V_{DC′}, which corresponds to the output of the normalization circuit 1 and represents the output signal y, corresponding to the normalization of the input signal x, in this case a normalized voltage V̅.

As shown in FIG. 3, as an example, the output signal y can then be fed to an ADC driver or directly to an ADC converter, to be converted into a digital format, so as to be available for any further digital processing.

In more detail, the first circuit path 2, as an example, comprises: a buffer stage 10 (e.g. a unity gain amplifier), which receives the input voltage V and provides a buffered signal; a high-pass filter stage 12, which is coupled at the output of the buffer stage 10 and receives the buffered signal and implements a high-pass filtering action with a high-pass cut-off frequency to provide a high-pass filtered signal (with removed DC component and signal shifted down and centered around zero); and a first gain stage 14, coupled at the output of the high-pass filter stage 12 and configured to provide an amplified signal, in particular amplified by the gain factor G.

In the embodiment shown in FIG. 3, the first gain stage 14 as an example comprises: a first sub-stage 14a, which receives the high-pass filtered signal and is configured to compensate for any signal attenuation deriving from the filtering action (so that the amplitude of the buffered signal is not changed); and a second sub-stage 14b, which is coupled to the output of the first sub-stage 14a and is configured to implement the amplification by the gain factor G, so as to provide at the output the first amplified filtered signal G·V_{AC}. In alternative embodiments, the first sub-stage 14a may be omitted; as a further alternative, the amplification by the gain factor G can be performed by multiple sub-stages, each amplifying the respective input signal by a respective gain sub-factor.

In particular, with a frequency fₛ of the input signal, the high-pass cut-off frequency can be higher than fₛ/10, preferably higher than fₛ/8, more preferably higher than fₛ/5.

The second circuit path 4 comprises: a respective buffer stage 20 (e.g. a unity gain amplifier), which receives the input voltage V and provides a buffered signal; a subtractor stage 21, which receives the buffered signal and subtract to the same signal the constant DC component

$${V}_{D C} = \frac{( {V}_{out\_min} + {V}_{out\_max} )}{2} ,$$

to provide at the output a subtracted signal having the DC-shift component and the rapidly varying AC component (V_{DC′}+V_{AC}), where V_{out_min} and V_{out_max} values represent the minimum value and maximum value of all possible inputs to the normalization circuit 1 (in this case, V_{out_min}=xₘᵢₙ and V_{out_max}=xₘₐₓ); a low-pass filter stage 22, which is coupled at the output of the subtractor stage 21 and receives the subtracted signal and implements a low-pass filtering action with a low-pass cut-off frequency to provide a low-pass filtered signal; and a second gain stage 24, coupled at the output of the low-pass filter stage 22 and configured to provide an amplified signal, in particular amplified by the same gain factor G (equal to and matching the gain of the first gain stage 14, in particular of the second sub-stage 14b of the same first gain stage 14). Accordingly, the output of the low-pass filter stage 22 thus corresponds to the DC shift component V_{DC′}, so that the output of the second gain stage 24 corresponds to the second amplified filtered signal G·V_{DC′}.

In alternative embodiments, the second gain stage 24 may comprise a respective sub-stage configured to compensate for any signal attenuation deriving from the filtering action. Alternatively, the amplification by the gain factor G can be performed by multiple sub-stages, each amplifying the respective input signal by a respective gain sub-factor.

In a further alternative embodiment (here not shown), the normalization circuit 1 may comprise a gain stage common to both the first and second paths 2, 4. This common gain stage may for example comprise a control element configured to alternatively (or sequentially) allow the high pass filtered and low pass filtered components to be amplified. In this way, a single gain stage may be used for both paths for performing the amplification operation, reducing the overall size of the normalization circuit 1.

In particular, with a frequency fₛ of the input signal, the low-pass cut-off frequency can be lower than fₛ/20, preferably lower than fₛ/50, more preferably lower than fₛ/100.

FIG. 4 shows a possible, fully analogic, circuit implementation of the normalization circuit 1 discussed above.

The various stages of the first and second circuit paths 2, 4 are highlighted in the same FIG. 4, for clarity of depiction; the same stages are denoted with the same reference numbers and are not discussed in detail herein, their implementation being clear in light of the above discussion. It is underlined however that all the stages are implemented solely and exclusively with analog circuit components, namely resistors, capacitors, operational amplifiers, voltage generators.

With reference to FIG. 5, an electronic system 100 according to a further aspect of the present solution is disclosed.

The electronic system 100 comprises a first electronic device 101 configured to generate an output signal representative of an output voltage or an output current of the same first electronic device 101; the normalization circuit 1, configured to receive the output signal as the input signal x and provide a normalized signal as the output signal y; and a second electronic device 102 configured to receive the output signal y provided by the normalization circuit 1.

According to a possible embodiment, the first electronic device 101 is a power converter device (e.g. a buck converter) and the second electronic device 102 is an analog to digital converter device, which receives the output signal and converts it into digital, so as to make it available for further processing (e.g. for predictive maintenance analysis and/or power management of the power converter device).

The advantages of the proposed solution are clear from the preceding description.

In any case, it is underlined that the disclosed normalization circuit 1 provides a real-time, continuous power efficient and more accurate normalization, as compared to digital complex solutions that may be subjected to errors, like quantization errors.

In particular, the ability to perform real-time normalization without a digital conversion makes the disclosed solution particularly valuable for applications requiring immediate signal conditioning and analysis.

The normalization circuit 1 moreover accounts for offset sensitivity issues, properly dealing with slow variations or changes over time of the DC component of the input signal to be normalized.

Therefore, the disclosed solution can be used to normalize even data having a very small variations (e.g. even as small as 100 microvolts for voltage signals), protecting these small variations from offsets which may have comparable or even higher values.

The disclosed solution is particularly useful to implement predictive maintenance solutions, e.g. of power electronic systems.

In general, the disclosed normalization circuit 1 can be easily integrated or embedded, addressing the need for real-time data normalization in various electronic systems.

Finally, it is clear that modifications and variations may be made to what is described and illustrated herein without thereby departing from the scope of the present invention, as defined in the attached claims.

In particular, in a possible alternative embodiment, the first and second circuit paths 2, 4 could share a same gain stage, in common. This common gain stage could be coupled to the output of the summing stage 6, to provide the output signal y (in this case, the first and second circuit paths 2, 4 would not include a respective gain stage).

Moreover, according to a further possible embodiment, the first and second circuit paths 2, 4 could share a same buffer stage, in common. This common buffer stage could be arranged at the input of the normalization circuit 1, to provide a buffered input signal to both the first and the second circuit paths 2, 4 (in this case, the first and second circuit paths 2, 4 would not have a respective buffer stage).

In one alternative embodiment (not shown) the buffer stage 10, 20 for the first and/or second paths 2, 4 could be omitted. In this case, the high pass filter stage 12 and the low pass filter stage 22 may comprise internally a respective buffer unit or may have a structure not requiring a buffering operation.

In general, it is again underlined that other circuit implementation for the normalization circuit 1 could be envisaged, different from the exemplary one depicted in the above discussed FIG. 4.

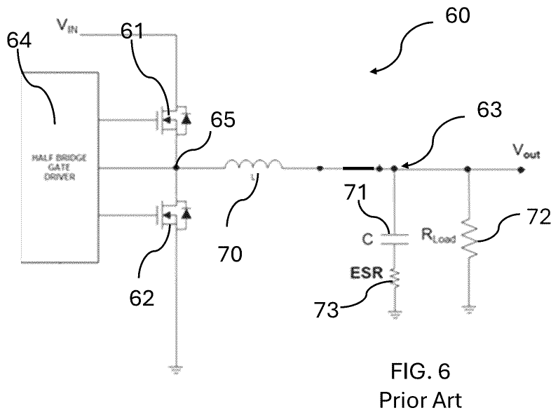

With reference to FIG. 6, it is schematically shown a known (by itself) first device 60, for example a power converter device (e.g. a buck converter).

The first device 60 comprises a first switching transistor 61, a second switching transistor 62 (for example both of the N-type), an output stage 63 and a gate driver 64.

Typically, the first switching transistor 61 comprises a respective gate terminal connected to the gate driver 64, a respective source terminal connected to a first supply line (e.g., Vin) and a respective drain terminal connected to a phase node 65 of the first device 60. The second switching transistor 62 comprises a respective gate terminal connected to the gate driver 64, a respective source terminal connected to the phase node 65 and a respective drain terminal connected to a second supply line (e.g., mass).

In the following, the terms “downstream” and “upstream” are used considering a direction with orientation from the device 60 to the output node (Vout).

Exemplarily the output stage 63 of the first device 60 is connected downstream the phase node 65 and comprises an inductor 70, a capacitor 71 and a load 72 (schematically represented as a resistor). The inductor 70 is typically connected between the phase node 65 and a first output node (Vout), with the capacitor 71 and the load 72 connected between the first output node and the second supply line (e.g., mass).

The Applicant has observed that the capacitance value of the capacitor 71 tends to change over time, for example due to aging phenomena. This change, for example, occurs with capacitor 71 of the electrolytic type due to electrolytic migration.

It is known that each capacitor of the electrolytic type is characterized by a determined value of Equivalent Series Resistance (ESR in the following) i.e., the internal resistance of the capacitor that appears in series with its ideal reactance and that is representative of, for example, energy loss, primarily dissipated as heat. This is schematically represented in FIG. 6 with resistor 73.

The Applicant has observed that, during operation, the monitoring of the ESR value could give a hint on the operational status of the first device 60. For example, monitoring an increased value of the ESR above a certain threshold (for example 3 times the initial or nominal ESR of the capacitor) could indicate that the converter (or the capacitor) has degraded beyond repair.

According to an aspect, an electronic system comprises a comparison circuit to be used to monitor the ESR during operation of the device, for example the first device.

According to an embodiment of the present solution, the comparison circuit is implemented through a pure analog circuitry. The Applicant has observed that the analog implementation simplifies the production and/or operation of the comparison circuit.

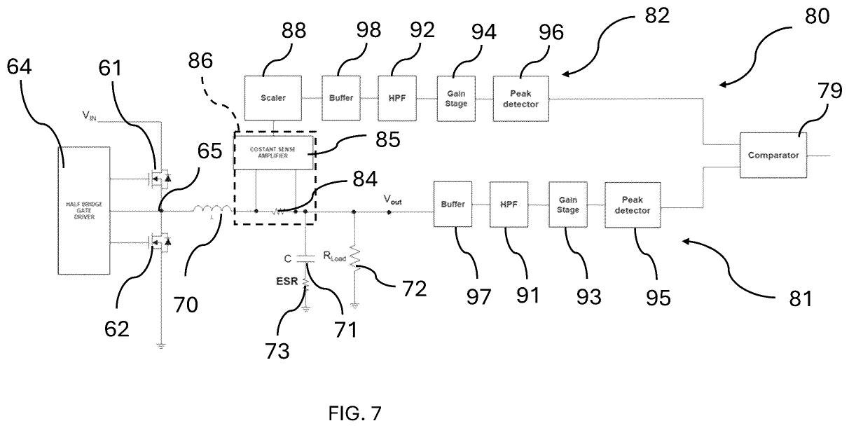

An embodiment of the comparison circuit is shown in FIG. 7, in which the comparison circuit is indicated with reference number 80. Exemplarily the comparison circuit 80 is used in combination with the first device 60 of FIG. 6, with same elements identified by the same reference numbers.

Exemplarily the comparison circuit 80 comprises a first branch 81 connected to the first output node Vout, a second branch 82 connected downstream the inductor 70 and upstream the capacitor 71 and a comparison unit 79 connected downstream of the first and second branches 81, 82 and structured to compare a first and second output signals of the first 81 and second branch 82, respectively.

The first branch 81 is structured to generate the first output signal representative of a (actual) voltage ripple at the output node (Vout).

The second branch is structured to generate the second output signal representative of a theoretical voltage ripple at the output node representative of a degraded (or aged) condition of the first device (or of the capacitor). The theoretical voltage ripple is obtained as a function of a current flowing in the inductor 70 and of a nominal (or initial) ESR value of the capacitor 71 multiplied by a constant N. Preferably N is in the range 1-10, for example N is equal to 3.

The Applicant has observed that the voltage ripple at the output node is a function of the ESR and the current flowing in the inductor 70. At high switching frequencies of the converter, the mathematical relationship is:

$$V r i p p l e \approx E S {R}^{⋆} Δ i L$$

With Vripple being the ripple in the voltage at the output node, ESR being the initial (or nominal) ESR value of the capacitor 71 and ΔiL being the current flowing in the inductor 70.

As said above, the Applicant has observed that, with the aging of the converter, the ESR tends to increase with consequent increase in the voltage ripple at the output node. The second output signal is therefore representative of a theoretical situation in which the capacitor 71 has degraded beyond repair. In fact, by multiplying the ESR by the constant N, it is possible to simulate a condition in which the ESR value is N-times bigger than the nominal (or initial) one.

Instead, the first output signal is representative of the real condition of the ESR. In fact, the output node is downstream of the capacitor 71 and therefore it is influenced by the real value the ESR (which determines a certain voltage ripple in the Vout).

By comparing these two signals, it is therefore possible to diagnose the status of the capacitor and to detect a condition in which the real voltage ripple (first output signal) is lower or bigger than the theoretical voltage ripple (second output signal) associated with a degraded capacitor (increased ESR).

Exemplarily, the second branch 82 comprises a sensing stage 86 connected downstream of the inductor 70 and structured to measure the current flowing in the inductor 70. Exemplarily, the sensing stage 86 comprises a sensing resistor 84 to convert the current flowing in the inductor 70 in a voltage signal and a Constant Sense Amplifier (CSA) stage 85 comprising an operational amplifier structured to amplify the voltage signal generated by the sensing resistor. In this way, the Applicant has observed that it is possible to easily extract the value of the current flowing in the inductor.

The second branch 82 further comprises a scaler 88 structured to modulate the signal received from the sensing unit 86. The modulation introduces, in the signal, a dependency on the (nominal) ESR multiplied by the constant value N. Exemplarily the modulation further removes, from the signal, a dependency from the sensing stage 86, for example a dependency from a resistance value of the sensing resistor 84 and/or from a gain factor of the CSA stage 85. In this way, it is possible to generate a signal (using analog circuitry only) clean from any disturbances introduced by the sensing stage 86.

Exemplarily, the first branch 81 and the second branch 82 respectively comprises a first filter stage 91 and a second filter stage 92, for example a respective high pass filter stage. Exemplarily the first filter stage 91 and the second filter stage 92 have a respective cut-off frequency higher than fs/10, preferably higher than fs/8, more preferably higher than fs/5, (fs being the switching frequency).

Exemplarily, the first branch 81 and the second branch 82 respectively comprises a first gain stage 93 and a second gain stage 94 downstream of the first filter stage 91 and the second filter stage, respectively. The first and second gain stages 93 and 94 are configured to amplify the respective signal received from the first filter stage 91 and the second filter stage 92, respectively. Exemplarily, the first and second gain stages 93, 94 are characterized by a respective constant gain factor G.

Exemplarily, the first branch 81 and the second branch 82 respectively comprises a first peak detector 95 and a second peak detector 96 downstream of the first gain stage 93 and the second gain stage 94, respectively. The first and second peak detectors 95, 96 are configured to detect a respective maximum value of the signal received from the first gain stage 93 and second gain stage 94, respectively, to generate the first output signal and the second output signal. The Applicant has observed that the use of a peak detector allows reducing and/or eliminating the influence of the phase shift in the comparison operation.

Exemplarily, the first branch 81 comprises a first buffer stage 97 connected upstream the first filter stage 91 and (directly) connected to the output node (Vout).

Exemplarily, the second branch 82 comprises a second buffer stage 98 connected upstream of the second filter stage 92 and downstream of the scaler 88.

Exemplarily the first and second buffer stages may be a unity gain amplifier.

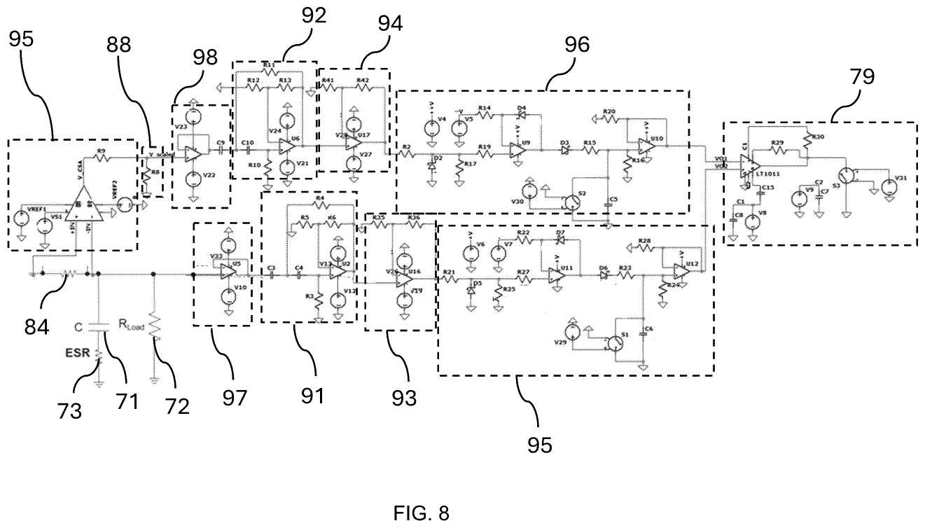

FIG. 8 shows a possible, fully analogic, circuit implementation of the comparison circuit 80 discussed above.

The various stages of the first and second branches 81 and 82 are highlighted in FIG. 8 using the same reference numbers for clarity. As clear, all the stages are implemented solely and exclusively with analog circuit components, e.g., resistors, capacitors, operational amplifiers, voltage generators.

As said above, the comparison unit 79 (e.g., a comparator) is structured to receive the first and second output signals from the first and second branches 81, 82 and to compare these two signals to generate a diagnostic signal representative of the status of the first device (or of the capacitor 71).

For example, the comparison unit 79 is able to generate a 0/1 signal, with the diagnostic signal being:
“0” for a condition in which the first output signal is lower than the second output signal (i.e., real ESR value smaller than the theoretical critical ESR value), and
“1” for a condition in which the first output signal is greater than the second output signal (i.e., real ESR value higher than or equal to the theoretical critical ESR value).

In this way, a simple and low power demanding information on the status of the first device can be obtained.

What is claimed is:

1. A normalization circuit, configured to receive an input signal and to provide a normalized output signal as a result of a normalization of the input signal, the normalization circuit comprising:
a first circuit path, configured to implement a high pass filtering of the input signal to provide a high-pass filtered component as a function of an AC component of the input signal;
a second circuit path, configured to implement a low pass filtering of the input signal to provide a low-pass filtered component as a function of a DC-shift component of the input signal, representing DC-level changes; and
a summing stage, coupled at outputs of the first and second circuit paths so as to provide at a respective output a sum signal as a function of a sum of the high-pass and low-pass filtered components;
wherein the normalization circuit comprises a gain stage configured to set a common gain factor for the AC and DC-shift components of the input signal, so that the respective output of the summing stage provides the normalized output signal as the result of the normalization of the input signal.

2. The normalization circuit according to claim 1, wherein the normalization circuit has a fully analog implementation.

3. The normalization circuit according to claim 1, wherein:
the normalization maps the input signal, with input values within an input range between a minimum input value and a maximum input value, into the normalized output signal, with output values within an output range between a minimum output value and a maximum output value; and
the minimum and maximum output values are set to negative and positive values, respectively, having an equal absolute value.

4. The normalization circuit according to claim 1, wherein the normalized output signal is the result of the normalization of the input signal according to a mapminmax formula:
$$y = ( \frac{( {y}_{max} - {y}_{min} ) \cdot ( x - {x}_{min} )}{{x}_{max} - {x}_{min}} ) + {y}_{min}$$
wherein y is the normalized output signal, xₘᵢₙ and xₘₐₓ are respective minimum and maximum values of an input range for the input signal and yₘᵢₙ and yₘₐₓ are respective minimum and maximum values of an output range for the normalized output signal.

5. The normalization circuit according to claim 4, wherein the normalized output signal oscillates in a symmetrical range centered at zero, between yₘᵢₙ=−K and yₘₐₓ=+K.

6. The normalization circuit according to claim 5, wherein
the mapminmax formula is reformulated as:
$$y = G \cdot {x}_{{DC}^{′}} + G \cdot {x}_{A C}$$
x_{DC′} is the DC-shift component of the input signal, and G is the common gain factor, given by 2K/(xₘₐₓ−xₘᵢₙ);
the gain stage comprises a first gain stage being part of the first circuit path and a second gain stage being part of the second circuit path;
the first circuit path is configured to perform a high-pass filtering and amplification by the common gain factor G of the input signal, so as to provide at a corresponding output a first amplified filtered signal corresponding to the product term G·x_{AC}, wherein x_{AC} is the AC component of the input signal;
the second circuit path is configured to perform a low-pass filtering and amplification by the common gain factor G of the input signal, so as to provide at a respective output a second amplified filtered signal corresponding to the product term G·x_{DC′}; and
the summing stage is configured to receive the first and second amplified filtered signals and to provide at the respective output a sum signal G·V_{AC}+G·V_{DC′}, which corresponds to the normalized output signal, wherein V_{AC} is AC component voltage and V_{DC′} is DC-shift component voltage.

7. The normalization circuit according to claim 1,
wherein the first circuit path comprises:
a high-pass filter stage, which is configured to implement a high-pass filtering action with a high-pass cut-off frequency to provide a high-pass filtered signal; and
a first gain stage, coupled at an output of the high-pass filter stage and configured to provide a first amplified signal, amplified by the common gain factor, which corresponds to the high-pass filtered component; and
wherein the second circuit path comprises:
a subtractor stage, which is configured to receive the input signal and subtract a constant DC component of the input signal, to provide a subtracted signal having the DC-shift component and the AC component;
a low-pass filter stage, which is coupled at an output of the subtractor stage and is configured to receive the subtracted signal and implement a low-pass filtering action with a low-pass cut-off frequency to provide a low-pass filtered signal having a sole DC-shift component; and
a second gain stage, coupled at an output of the low-pass filter stage common provide a second amplified signal, amplified by the gain factor, which corresponds to the low-pass filtered component.

8. The normalization circuit according to claim 7, wherein the first gain stage comprises:
a first sub-stage, which is configured to compensate for attenuation of the signal derived from the high-pass filtering action by the high-pass filter stage; and
a second sub-stage, which is coupled to an output of the first sub-stage and is configured to implement the amplification by the common gain factor.

9. The normalization circuit according to claim 7, wherein, with a frequency fₛ of the input signal, the high-pass filtering cut-off frequency is higher than fₛ/10.

10. The normalization circuit according to claim 7, wherein, with a frequency fₛ of the input signal, the low-pass filtering cut-off frequency is lower than fₛ/20.

11. The normalization circuit according to claim 1, wherein:
the first circuit path further comprises a first buffer stage, which is configured to receive the input signal and provide a first buffered signal; and
the second circuit path further comprises a second buffer stage, which is configured to receive the input signal and provide a second buffered signal.

12. An electronic system, comprising:
a first electronic device configured to generate a first output signal representative of an output voltage or an output current of the first electronic device;
a normalization circuit, configured to receive the first output signal of the first electronic device as an input signal, and to provide a normalized output signal as a result of a normalization of the input signal, the normalization circuit comprising:
a first circuit path, configured to implement a high pass filtering of the input signal to provide a high-pass filtered component as a function of an AC component of the input signal;
a second circuit path, configured to implement a low pass filtering of the input signal to provide a low-pass filtered component as a function of a DC-shift component of the input signal, representing DC-level changes; and
a summing stage, coupled at outputs of the first and second circuit paths so as to provide at a respective output a sum signal as a function of a sum of the high-pass and low-pass filtered components;
wherein the normalization circuit comprises a gain stage configured to set a common gain factor for the AC and DC-shift components of the input signal, so that the respective output of the summing stage provides the normalized output signal as the result of the normalization of the input signal; and
a second electronic device configured to receive the normalized output signal provided by the normalization circuit.

13. The electronic system according to claim 12, wherein the first electronic device is a power converter device, and the second electronic device is an analog-to-digital converter device.

14. An electronic system comprising:
an electronic device comprising;
a first switching transistor and a second switching transistor each having a respective terminal connected to a phase node of the electronic device; and
an output stage connected downstream of the phase node and comprising:
an inductor connected between the phase node and an output node; and
a capacitor and a load connected between the output node and a supply line, wherein the capacitor has an equivalent series resistance value; and
a comparison circuit connected to the electronic device and comprising:
a first branch connected to the output node;
a second branch connected downstream of the inductor and upstream of the capacitor; and
a comparator connected downstream of the first and second branches and configured to compare first and second output signals of the first and second branches, respectively, wherein the first output signal is representative of a real voltage ripple at the output node, and the second output signal is representative of a theoretical voltage ripple at the output node.

15. The electronic system of claim 14, wherein the theoretical voltage ripple is a function of a current flowing in the inductor and of a nominal equivalent series resistance value of the capacitor multiplied by a constant in a range of 1-10.

16. The electronic system of claim 14, wherein the comparison circuit is fully analog.

17. The electronic system of claim 14, wherein the first branch comprises:
a first buffer stage connected to the output node;
a first filter stage connected downstream of the first buffer stage;
a first gain stage connected downstream of the first filter stage; and
a first peak detector connected downstream of the first gain stage.

18. The electronic system of claim 14, wherein the second branch comprises:
a sensing stage configured to measure a current flowing in the inductor, wherein the sensing stage is connected downstream of the inductor; and
a scaler configured to modulate a signal received from the sensing stage, wherein the scaler is connected downstream of the sensing stage.

19. The electronic system of claim 18, wherein the second branch further comprises:
a second buffer stage connected downstream of the scaler;
a second filter stage connected downstream of the second buffer stage;
a second gain stage connected downstream of the second filter stage; and
a second peak detector connected downstream of the second gain stage.

20. The electronic system of claim 14, wherein comparator generates a diagnostic signal representative of a status of the electronic device based on the compare of the first and second output signals.
